(19) United States
(12) Patent Application Publication
(10) Pub. No.: US 2004/0169530 A1
(43) Pub. Date: Sep. 2, 2004

(54) Method and apparatus for robust biasing of bipolar and BiCMOS differential architectures

(75) Inventor: Gabriele Manganaro, Boxborough, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Engim, Inc., Acton, MA (US)

(21) Appl. No.: 10/672,061

(22) Filed: Sep. 26, 2003

Related U.S. Application Data
(60) Provisional application No. 60/414,603, filed on Sep. 27, 2002.

(51) Int. Cl. H03F 3/45

(52) U.S. Cl. 327/52

(57) ABSTRACT

A base bias circuit generates a bias voltage for a bipolar transistor. The base bias circuit includes a current mirror circuit which tracks current through a current source which drives emitter current through the bipolar transistor. A primary biasing bipolar transistor and a secondary bipolar transistor have a β which tracks the β of the bipolar transistor. The primary biasing bipolar transistor receives current from the current source through a current mirror circuit to develop the bias voltage. A bias resistor coupled between the bias voltage and the base of the primary biasing bipolar transistor tracks resistance variations in the base resistor. The secondary biasing transistor tracks changes in base current to the bipolar transistor and supplies additional current to the primary biasing transistor to compensate for changes in β.

### RELATED APPLICATION

This application claims the benefit of U.S. Provisional Application No. 60/414,603, filed on Sep. 27, 2002. The entire teachings of the above application are incorporated herein by reference.

### BACKGROUND OF THE INVENTION

Analog differential circuits are commonplace in high performance integrated as well as discrete circuit technology. Bipolar junction transistors (bipolar transistors) are increasingly used as input devices for differential architectures as pure bipolar, BiCMOS and SiGe heterojunction (HBT) technologies become the preferred choices for very-high-speed integrated circuits.

A bipolar transistor is an active semiconductor device formed by two P-N junctions (a base-emitter junction and a base-collector junction). An NPN bipolar transistor has a thin region of P-type material (the base) between two regions of N-type material (the emitter and the collector). A PNP bipolar transistor has a thin region of N-type material (the base) between two regions of P-type material (the emitter and the collector).

The range of operation of a bipolar transistor includes a cut-off region, an active region and a saturation region based on the biasing of the P-N junctions. The bipolar transistor operates in the cut-off region while both the emitter-base junction and the collector-base junction are reverse biased. While operating in the cut-off region, no significant current flows through the bipolar transistor.

As the voltage at the base is increased, the base emitter junction becomes forward biased and the bipolar transistor operates in the active region of operation. While in the active region of operation, the collector-base junction remains reversed biased and the bipolar transistor operates as an amplifier with the current flowing in the base controlling the current flowing in the collector. The collector current (Ic) is approximately proportional to the base current (Ib), related by the static current gain β=I_{c}/I_{b}.

While both the emitter-base junction and the collector-base junction are forward biased, the bipolar transistor operates in the saturation region. The bipolar transistor is “saturated”, that is, the collector current cannot increase any further even with continued increase in base current. While the bipolar transistor is “saturated”, the output A.C. signal is clipped resulting in a distorted output signal.

FIG. 1 is a schematic of a prior art bipolar transistor circuit 100 including a single-ended input-differential output amplifier 104 and a biasing circuit 102.

The differential amplifier 104 includes a pair of bipolar transistors Q1, Q2. Load resistors Rc coupled between respective collector of bipolar transistors Q1, Q2 and the power supply voltage V_{cc} form the load for the differential amplifier 104.

The single-ended input signal RFᵢₙ to the differential amplifier 104 is A.C. coupled to the base of bipolar transistor Q1 through a capacitor CIN. The differential output signal V_{OUT} is output from the collectors of bipolar transistors Q1, Q2. The collector of bipolar transistor Q3 is coupled to the emitters of bipolar transistors Q1, Q2. Bipolar transistor-resistor pair Q3-R3 provides the tail current for the differential amplifier.

A biasing circuit 102 sets the respective quiescent base voltage (V_{b1}, V_{b2}) for each of the bipolar transistors Q1 and Q2. The design of a biasing circuit is challenging for an amplifier with a large output voltage swing and limited power supply range. The major design challenge is choosing a quiescent base voltage for bipolar transistors Q1, Q2 which simultaneously keeps bipolar transistors Q1 and Q2 in the active region of operation when the A.C. output voltage V_{OUT} is at full swing and keeps bipolar transistor Q3 in the active region of operation for all input voltages, and over all process and temperature variations. Moreover, the biasing circuit must account for process and temperature variation in order to preserve the desired quiescent point of all devices in the amplifier under all conditions.

If the quiescent base voltage of bipolar transistors Q1 and Q2 is chosen too high, the base-collector junction of bipolar transistors Q1, Q2 may be forward biased resulting in bipolar transistors Q1 and Q2 operating in the saturation region. If the base voltage of bipolar transistor Q1 and Q2 is chosen too low, the respective base-emitter voltage drop on bipolar transistor Q1, Q2 may force the collector voltage of bipolar transistor Q3 to an excessively low level resulting in the forward biasing of the base-collector junction of bipolar transistor Q3 and resulting in bipolar transistor Q3 operating in the saturation region.

The biasing circuit 102 includes a current source that includes bipolar transistor-resistor pairs Q3-R3, Q4-R4, and Q5-R5. The bias current I_{bias} is replicated in bipolar transistor-resistor pairs Q4-R4 and Q3-R3 based on geometric ratios with bipolar transistor-resistor pair Q5-R5. The biasing circuit 102 also includes bias resistor Rbias, bipolar transistor Q6 and base resistor RB. Bipolar transistor-resistor pair Q4-R4 defines the current through bias resistor Rbias and thus defines the quiescent bias voltage (V_{bias}) for the amplifier 104.

Ideally, the bias current (I_{bias}) in the biasing circuit 102 is constant through the bias resistor Rbias, and the base voltage (V_{b1}, V_{b2}) at the respective base of each of bipolar transistors Q1 and Q2 is constant. However, V_{bias} can change due to variations in temperature and power supply voltage. The biasing circuit 102 ensures that a slight reduction in the power supply voltage V_{cc} does not directly impact the output voltage swing. With a decrease in the power supply voltage, the quiescent base voltage (V_{b1} V_{b1}) of bipolar transistor Q1 is proportionally reduced (through bias resistor Rbias) with respect to the quiescent collector voltage of bipolar transistor Q1 (through load resistor Rc), preserving the reverse biasing of the base-collector junction of bipolar transistor Q1. However, as the respective emitter of each bipolar transistor Q1, Q2 is coupled to the collector of bipolar transistor Q3, the decrease in the voltage at the respective base of bipolar transistors Q1 and Q2 results in a decrease in the quiescent collector voltage of bipolar transistor Q3. The decrease in the collector voltage of bipolar transistor Q3 may result in bipolar transistor Q3 operating in the saturation region. Therefore, the quiescent state of bipolar transistor Q3 is directly dependent on the power supply voltage.

The bias voltage (V_{bias}) is also dependent on the resistance of bias resistor Rbias. The resistance of a material is dependent on resistivity which varies with temperature or because of process manufacturing (parameter variation). An increase in the resistance of bias resistor Rbias with a constant bias current (I_{bias}) results in a decrease in the respective voltage at the bases of bipolar transistor Q1, Q2. The decrease in base voltage results in a corresponding decrease in voltage at the collector of bipolar transistor Q3 which may result in bipolar transistor Q3 operating in the saturation region. Variations in the resistance of bias resistor Rbias are completely unrelated to variations in bipolar transistors Q1-Q3 because the physics of these devices is different. Hence, the range of conditions over which the bias circuit provides the correct bias voltage to bipolar transistors Q1-Q3 is limited.

The bias voltage V_{bias} also varies due to changes in β (static current gain) of bipolar transistors Q1, Q2. The β of a bipolar transistor is the ratio of collector current Ic to base current Ib (β=I_{c}/I_{b}). There are circumstances in which the static current gain of a bipolar transistor can drop significantly from its nominal value. For example, at low temperature, β, drops due to lowered emitter injection efficiency, resulting in a decrease in collector current I_{c}. Moreover, β, can experience more than 50% variation over its nominal value due to parameter spread (process variation).

With high β values (typically 100 to 200), the base current I_{b} is negligible compared to the collector current I_{c} and the bias voltage V_{bias} is almost the same as the base voltage (V_{b1}, V_{b2}). The respective static collector current of bipolar transistors Q1 and Q2 is fixed by I_{bias} and the current mirror constituted by bipolar transistors Q3-Q6/R3-R5. Thus, a decrease in β results in a corresponding increase in base current.

With the increase in base current I_{b}, the bias voltage V_{bias} decreases due to the increased voltage drop across bias resistor Rbias. The decrease in bias voltage V_{bias} and the additional increased voltage drop across the base resistors RB reduces the respective quiescent base voltage of bipolar transistors Q1 and Q2. The decrease in the base voltage of bipolar transistors Q1, Q2 results in a corresponding decrease in the emitter voltage of bipolar transistors Q1, Q2 and may result in bipolar transistor Q3 entering the saturation region of operation. Therefore, a decrease in β due to temperature or parameter spread may result in a catastrophic failure because the base voltage V_{b1}, V_{b2} of bipolar transistors Q1, Q2 is no longer at the quiescent operating point and the biasing circuit 102 is unable to compensate for the change.

FIG. 2 is a schematic of an oscillator which includes a voltage controlled oscillator 208 which presents a like problem. The voltage controlled oscillator 208 includes differential pair bipolar transistors Q1-Q4 biased through base resistors RB1, RB2. However, to address the above noted problem, the bias resistor Rbias in the prior art biasing circuit 104 is replaced by a circuit including bipolar transistors Q8-Q10 and resistors RE1, RE11, RE12 and RB4 in biasing circuit 202. The respective quiescent base voltage of bipolar transistor Q1-Q4 is determined by the biasing circuit 202.

In contrast to biasing circuit 102 discussed in conjunction with FIG. 1, biasing circuit 202 does not suffer from the dependence on the upper power supply voltage V_{cc}, because the base voltage for bipolar transistors Q1-Q4 is obtained from bipolar transistors Q8, Q9 and bias resistor RB4 biased at constant current. Bipolar transistors Q8 and Q9 are selected to match bipolar transistors Q1-Q4, Q7 and resistor RB4 is selected to match base resistor RB. As temperature changes, bipolar transistors Q1-Q4 and Q7 are tracked by bipolar transistors Q8-Q9. Moreover, the devices are matched so that process variations on bipolar transistors Q1-Q4 and Q7 are tracked by bipolar transistors Q8-Q9.

Nevertheless, this biasing circuit 202 also suffers from the problem related to variations in β. In this case, an excess base current I_{b} is drawn through base resistors RB1, RB2. The excess base current results in an increase in the voltage drop across base resistors RB1, RB2. The excess base current is stolen from the emitter current of bipolar transistor Q11, reducing the current through resistor RB4, and bipolar transistors Q9, Q8. The reduction in current through RB4 results in a reduction in the bias voltage V_{bias} because V_{bias}=(base-emitter voltage V_{be} of bipolar transistor Q8+base emitter V_{be} of bipolar transistor Q9+I×RB4). Thus, a decrease in current (I) through RB4, reduces the bias voltage V_{bias}. The decrease in bias voltage further reduces the base voltage of bipolar transistors Q1-Q4, which may result in driving bipolar transistor Q7 into saturation.

### SUMMARY OF THE INVENTION

A biasing method for a bipolar transistor that is robust over a wide range of process and operating conditions is presented. To reduce the effect of current variations with changes in β, a bias resistor is coupled between the base and collector of a primary biasing bipolar transistor. By connecting the bias resistor between the base and collector of primary biasing bipolar transistor, the matching of the bias resistor with a base resistor coupled to the base of the bipolar transistor is not dependent on the primary biasing bipolar transistor β value. Instead, the match is only dependent on geometric matching of the base resistor and the bias resistor. To further compensate for changes in β reducing the bias voltage, a secondary biasing transistor tracks changes in base current to the bipolar transistor and supplies additional current to the primary biasing transistor.

A bipolar transistor circuit includes a primary bipolar transistor, a base resistor, a current source and a base bias circuit. The current source drives emitter current through the primary bipolar transistor. A base bias circuit generates the bias voltage that is applied to the base of the primary bipolar transistor. The base bias circuit includes a current mirror circuit which tracks current through the current source, a primary biasing bipolar transistor and a secondary biasing circuit. The bipolar transistor circuit includes several current mirrors which together form the current mirror circuit. The primary biasing bipolar transistor has a β which tracks the β of the primary bipolar transistor and which receives current through the current mirror circuit to develop the bias voltage. The secondary biasing circuit includes a secondary biasing bipolar transistor having a β which tracks the β of the primary bipolar transistor. The secondary biasing bipolar transistor receives current from the current mirror circuit. Changes in base current to the secondary biasing bipolar transistor cause changes in current to the primary biasing bipolar transistor.

A bias resistor may be coupled between the bias voltage and the base of the primary biasing bipolar transistor to track resistance variations in the base resistor. The current mirror circuit may include a first current mirror which provides collector current to the primary biasing bipolar transistor and a second current mirror which tracks base current through the secondary biasing bipolar transistor.

The primary bipolar transistor, the primary biasing bipolar transistor and the secondary biasing bipolar transistor may be NPN or PNP type.

In one embodiment, the biasing method is applied to the biasing of a differential amplifier and the primary bipolar transistor is any one of a pair of bipolar transistors in the differential amplifier. In an alternate embodiment the biasing scheme is applied to a differential voltage controlled oscillator and the primary bipolar transistor is any one of the plurality of bipolar transistors in the differential voltage controlled oscillator.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic of a single-ended input-differential output amplifier for high frequency (RF) including a prior art biasing circuit;

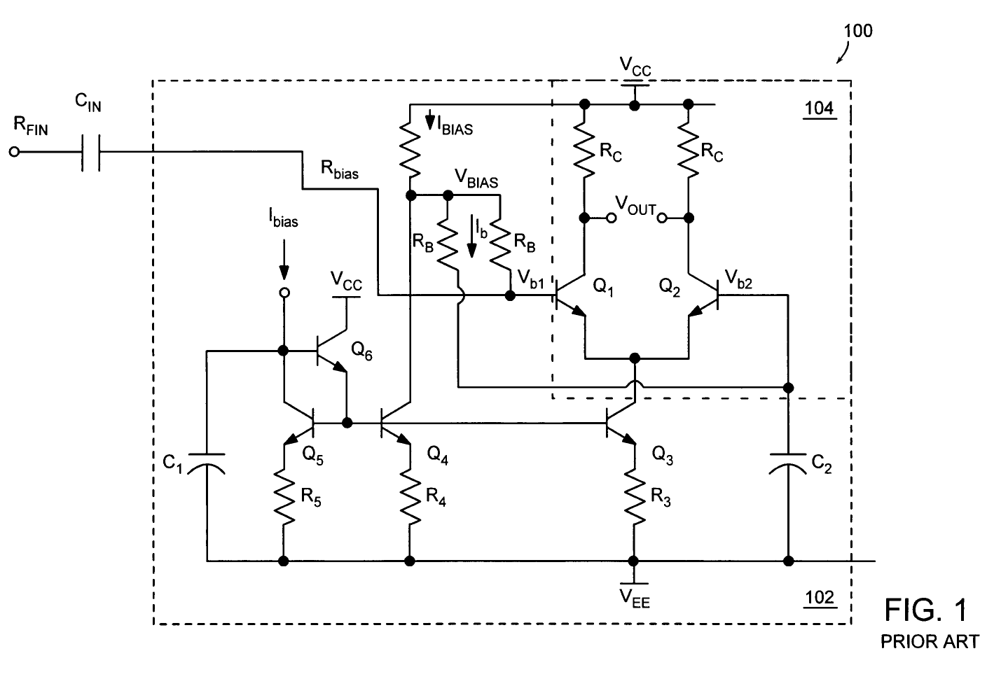

FIG. 2 is a schematic of a voltage controlled oscillator including a prior art biasing circuit;

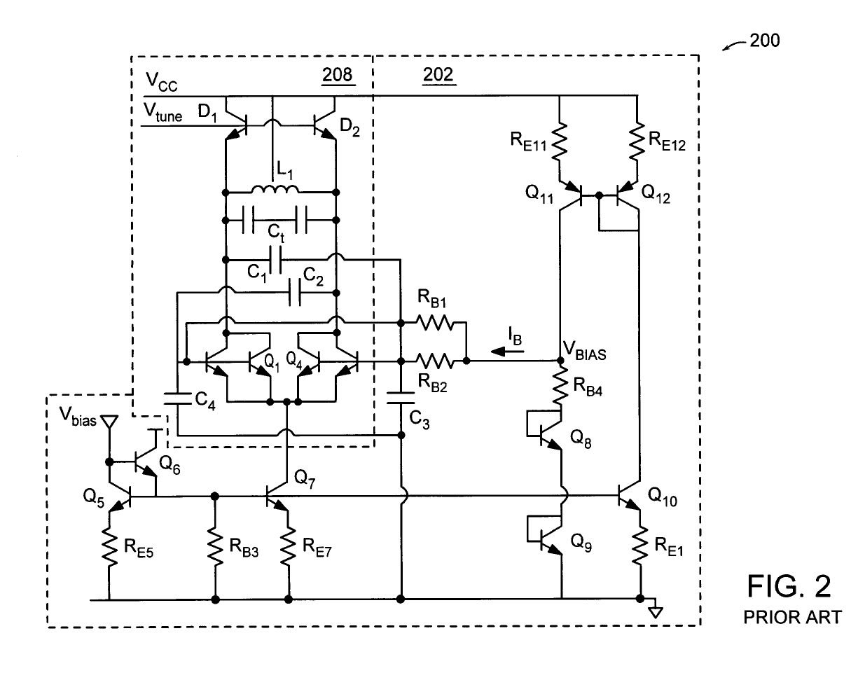

FIG. 3 is a schematic of a single-ended input-differential output amplifier and a biasing circuit according to the principles of the present invention;

FIG. 4 is a schematic of a single-ended amplifier and the biasing circuit shown in FIG. 3;

FIG. 5 is schematic of an alternate embodiment of the single-ended differential output differential amplifier shown in FIG. 3 with PNP bipolar transistors and the biasing circuit shown in FIG. 3; and

FIG. 6 is a schematic of a differential voltage controlled oscillator and the biasing circuit shown in FIG. 3.

### DETAILED DESCRIPTION OF THE INVENTION

A description of preferred embodiments of the invention follows.

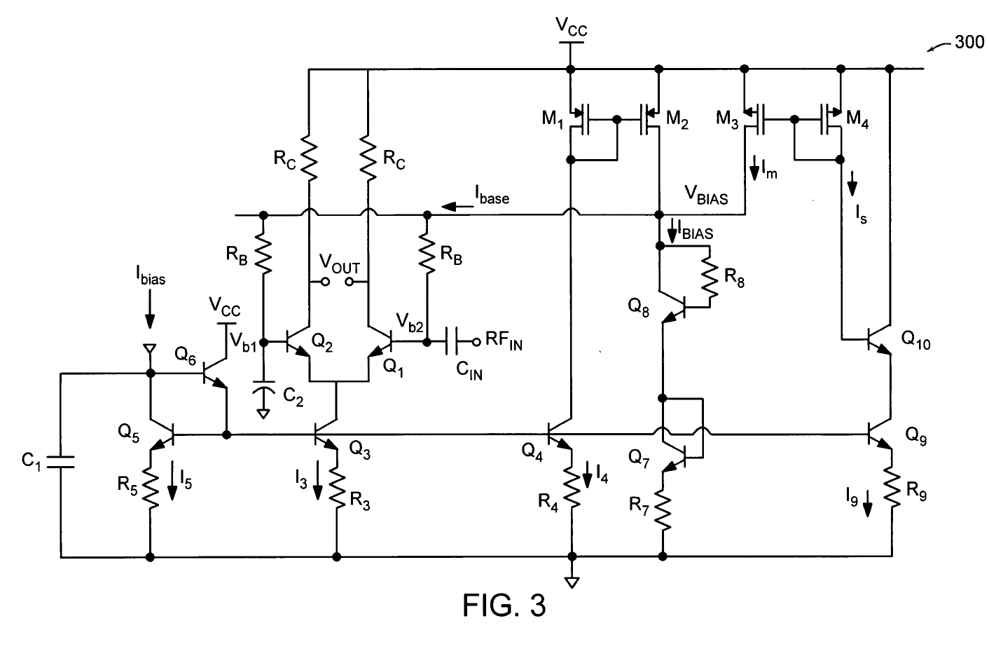

FIG. 3 is a schematic of a single-ended input-differential output amplifier and a biasing circuit according to the principles of the present invention. The single-ended input-differential output amplifier includes a pair of primary bipolar transistors Q1, Q2, load resistors Rc and base resistors Rb. Load resistors Rc are coupled between respective collector of bipolar transistors Q1, Q2 and V_{cc} to form the load for the differential amplifier. Base resistors Rb are coupled between the respective base of bipolar transistors Q1, Q2 and the biasing circuit. A capacitor C2 is coupled between the base of primary bipolar transistor Q2 and ground. The single-ended input signal RFᵢₙ, is A.C. coupled to the base of primary bipolar transistor Q1 through a capacitor CIN. The differential output voltage V_{OUT} is the voltage between the collectors of primary bipolar transistors Q1, Q2.

The biasing circuit sets the quiescent base voltage (V_{b1} V_{b2}) for primary bipolar transistors Q1, Q2 in the single-ended input-differential output amplifier and compensates for process variations, changes in power supply voltage and changes in P due to temperature variations or process variation. The biasing circuit includes a current source and a base bias circuit. The biasing circuit includes several current mirrors which together form a current mirror circuit.

The current source provides a constant emitter current 13 to the tail of the differential amplifier. The current source includes bipolar transistor Q6 and bipolar transistor-resistor pairs Q3-R3, Q4-R4, Q5-R5 and Q9-R9. Bipolar transistor-resistor pairs Q4-R4, Q3-R3 and Q9-R9 are output branches of the current source providing constant currents I₃ I₄ I₉ and bipolar transistor-resistor pair Q5-R5 is the input branch of the current source. The output branches of the current source mirror a DC current I₃ I₄ I₉, the magnitude of which is dependent on the geometric ratio of the output branch with the input branch.

The base bias circuit includes a primary biasing circuit which includes primary biasing bipolar transistor Q8 and a secondary biasing circuit including secondary biasing bipolar transistor Q10. The primary biasing circuit sets the quiescent base voltage (V_{b1}, V_{b2}) for primary bipolar transistors Q1, Q2, and the secondary biasing circuit tracks changes in the base current to primary bipolar transistors Q1, Q2 to compensate for changes in the static current gain β of primary bipolar transistors Q1, Q2. The secondary biasing circuit provides additional current Iₘ to compensate for changes in β requiring additional base current I_{base} which is taken from the bias current I_{bias}.

The base bias circuit also includes two current mirrors. A first current mirror including PMOS devices M1-M2, mirrors current I₄ through output branch Q4-R4 of the current source provide bias current I_{bias} to the primary biasing circuit to develop the bias voltage V_{bias} at the collector of the primary biasing bipolar transistor Q8. The current I₄ through the output branch including bipolar transistor-resistor pair Q4-R4 is sensed by PMOS device M1 and mirrored by PMOS device M2 to provide bias current I_{bias}. A second current mirror including PMOS devices M3-M4 mirrors base current Iₛ in the secondary biasing circuit to supply additional current to the primary biasing circuit to compensate for changes in β in primary bipolar transistor Q1. The base current Iₛ through bipolar transistor Q10 is sensed by PMOS device M4 and mirrored by PMOS device M3 to provide the additional current Iₘ. In an alternate embodiment using a pure bipolar process, PMOS devices M1-M4 in the current mirrors can be replaced with bipolar transistors.

The primary biasing circuit includes a primary biasing bipolar transistor Q8, bias resistor R8, bipolar transistor Q7 and resistor R7. The primary biasing bipolar transistor Q8 receives current I_{bias} from PMOS device M2 in the first current mirror. By connecting R8 between the base and collector of Q3, only the Q8 bias current flows through R8. Primary biasing bipolar transistor Q8, bias resistor R8, bipolar transistor Q7 and resistor R7 are selected to match the differential half-circuit of the differential amplifier that includes primary bipolar transistor Q1, base resistor RB, bipolar transistor Q3 and resistor R3 with proper geometric ratio. More specifically, primary biasing bipolar transistor Q8 matches primary bipolar transistor Q1 and has a β that tracks the β of primary bipolar transistor Q1, bias resistor R8 matches resistor RB, bipolar transistor Q7 matches bipolar transistor Q3, and resistor R7 matches resistor R3. The devices are matched so that variations due to process, temperature or bias conditions in the differential amplifier are reflected by the primary biasing circuit and vice-versa.

The emitter of primary biasing bipolar transistor Q8 is coupled to the collector of diode-coupled bipolar transistor Q7. Resistor R7 is coupled between the emitter of bipolar transistor Q7 and ground. The bias resistor R8 coupled between the base and collector of primary biasing bipolar transistor Q8 tracks resistance variations with temperature in the base resistors RB to compensate for changes in voltage across base resistors RB. By connecting R8 between the base and collector of primary biasing bipolar transistor Q8, the matching of bias resistor R8 with base resistor RB is not dependent on primary biasing bipolar transistor Q8's β value. Instead, the match is only dependent on geometric matching of base resistor Rb and bias resistor R8.

In an alternate embodiment, resistor R7 can be omitted if the voltage drop across resistor R7 is less than the forward biasing threshold voltage of the collector-base junction of bipolar transistor Q3. The omission of R7 is desirable for low voltage operation. Without resistor R7, the collector of bipolar transistor Q3 can be biased to a lower voltage than the base voltage while bipolar transistor Q3 is kept in the active region of operation.

The secondary biasing circuit compensates for changes in β in bipolar transistor Q1 by tracking changes in base current I_{base} to primary bipolar transistor Q1. The secondary biasing circuit in the biasing circuit includes bipolar transistor Q9, resistor R9 and secondary biasing bipolar transistor Q10 which match the devices in the differential half-circuit including bipolar transistor-resistor pair Q3-R3, and bipolar transistor Q1. Specifically, secondary biasing bipolar transistor Q10 has a β that tracks the β of the primary bipolar transistor Q1, and the emitter bias current 19 of bipolar transistor Q10 is chosen with proper geometric ratio to the emitter bias current 13 of bipolar transistor Q1. By doing so, the quiescent base current Iₛ of bipolar transistor Q10 proportionally matches quiescent base current I_{base} of bipolar transistor Q1. The base currents I_{base},Iₛ proportionally match regardless of bipolar transistor Q10's actual β value. Therefore, the base currents I_{base},Iₛ proportionally match even when β drops significantly from its nominal value.

The base current Iₛ of bipolar transistor Q10 is mirrored by PMOS device M3 in the second current mirror and sourced through base resistors RB. The mirror current Iₘ can be the same as Q10's base current Iₛ or there can be a geometric ratio between the mirrored current and the base current with the ratio dependent on the size of M3 and M4. Thus, if there is a drop in β in bipolar transistors Q1-Q2 and, consequently, the demand for base current I_{base} increases, this condition is reproduced by bipolar transistor Q10 and the necessary extra current Iₘ for bipolar transistor Q1-Q2 is supplied by M3.

Thus, the bias voltage V_{bias} does not change because bipolar transistor Q10 tracks bipolar transistor Q1's change in β and supplies the extra current Iₘ to bipolar transistor Q8 to maintain the bias voltage V_{bias}. The minor voltage drop across base resistors Rb due to increased base current I_{base} is matched by bias resistor R8 due to increased base current to bipolar transistor Q8. The ratio between the size of M3 and M4 is selected to also supply the necessary extra current Iₘ for the increased base current to bipolar transistor Q8 through bias resistor R8. Thus, the base voltage and emitter voltage of bipolar transistors Q1, Q2 does not drop significantly. With the additional current Iₘ from the secondary biasing circuit, the primary biasing circuit still follows the differential half-circuit ensuring proper biasing for the amplifier.

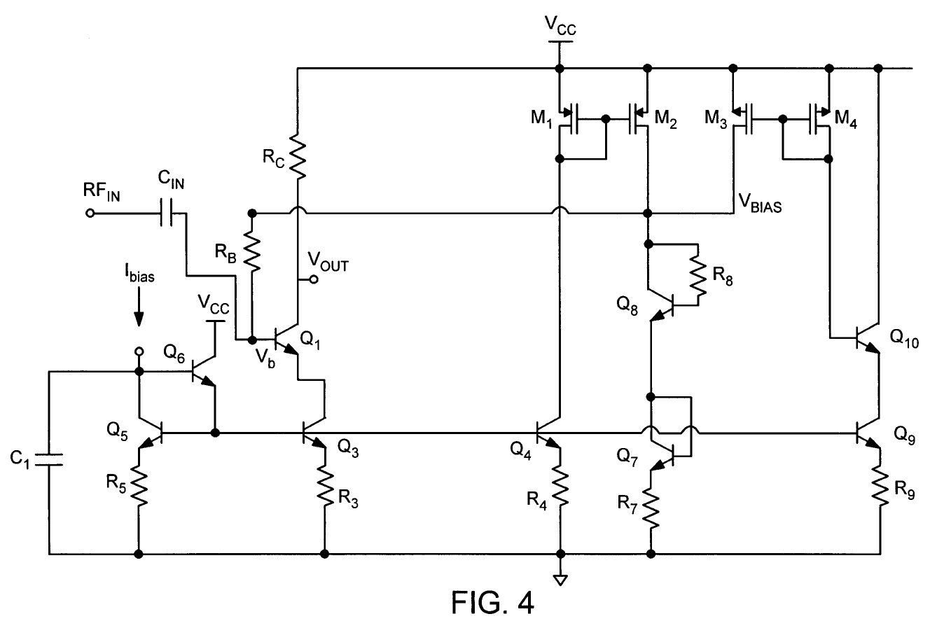

FIG. 4 is a circuit diagram of a single-ended amplifier and the biasing circuit shown in FIG. 3. The biasing circuit sets the quiescent base voltage for the bipolar transistor in the single-ended amplifier and compensates for process variations, changes in power supply voltage and changes in β due to temperature variation or process variation.

The single-ended amplifier includes primary bipolar transistor Q1, load resistor Rc and base resistor Rb. Load resistor Rc is coupled between the collector of bipolar transistor Q1 and V_{cc} to form the load for the single-ended amplifier. Base resistor Rb is coupled between the base of bipolar transistor Q1 and the biasing circuit. The single-ended input signal RFᵢₙ is A.C. coupled to the base of primary bipolar transistor Q1 through a capacitor C_{IN}. The differential output voltage V_{OUT} is the voltage at the collector of primary bipolar transistor Q1.

The biasing circuit sets the quiescent base voltage Vb for primary bipolar transistor Q1 in the single-ended amplifier and compensates for process variations, changes in power supply voltage and changes in β due to temperature variation or process variation. The biasing circuit includes the same current source and a base bias circuit described in conjunction with FIG. 3.

The current source includes bipolar transistor Q6 and bipolar transistor-resistor pairs Q3-R3, Q4-R4, Q5-R5 and Q9-R9 and provides a constant emitter current to bipolar transistor Q1. The base bias circuit includes a primary biasing circuit which includes primary biasing bipolar transistor Q8 and a secondary biasing circuit including secondary biasing bipolar transistor Q10. The primary biasing circuit including primary biasing bipolar transistor Q8, bias resistor R8, bipolar transistor Q7 and resistor R7 sets the quiescent base voltage Vb for primary bipolar transistor Q1. The secondary biasing circuit includes bipolar transistor Q9, resistor R9 and secondary biasing bipolar transistor Q10 and tracks changes in the base current to primary bipolar transistors Q1 to compensate for changes in β in primary bipolar transistor Q1.

The primary biasing bipolar transistor Q8 receives current from PMOS device M2 in a first current mirror. Primary biasing bipolar transistor Q8 tracks resistance variations with temperature in the base resistors RB to compensate for changes in voltage across base resistors RB. By connecting R8 between the base and collector of primary biasing bipolar transistor Q8, the matching of bias resistor R8 with base resistor RB is not dependent on primary biasing bipolar transistor Q8's β value. Instead, the match is only dependent on geometric matching of base resistor Rb and bias resistor R8.

The secondary biasing circuit compensates for changes in β in bipolar transistor Q1 by tracking changes in base current to primary bipolar transistor Q1. Secondary biasing bipolar transistor Q10 has a 13 that tracks the β of the primary bipolar transistor Q1. The emitter bias current of bipolar transistor Q1 is chosen with proper geometric ratio to the emitter bias current of bipolar transistor Q1. By doing so, the quiescent base current of bipolar transistor Q10 proportionally matches quiescent base current of bipolar transistor Q1. The base currents proportionally match regardless of bipolar transistor Q10's actual β value. Therefore, the base currents proportionally match even when β drops significantly from its nominal value.

The base current of bipolar transistor Q10 is mirrored by PMOS device M3 in the second current mirror and sourced through the RB resistors. Thus, if there is a drop in 13 in bipolar transistor Q1 and, consequently, the demand for base current increases, this condition is reproduced by bipolar transistor Q10 and the necessary extra current for bipolar transistor Q is supplied by PMOS device M3.

Thus, the bias voltage V_{bias} does not change because bipolar transistor Q10 tracks bipolar transistor Q1's change in β and supplies the extra current through the base current I_{base} to Q8 to maintain the bias voltage V_{bias}. The minor voltage drop across base resistors Rb due to increased base current I_{b} is matched by the increased base current to Q8 through bias resistor R8. Thus, the base voltage and emitter voltage of bipolar transistor Q1 does not drop significantly. With the additional current from the secondary biasing circuit, the primary biasing circuit still follows the differential half-circuit ensuring proper biasing for the amplifier.

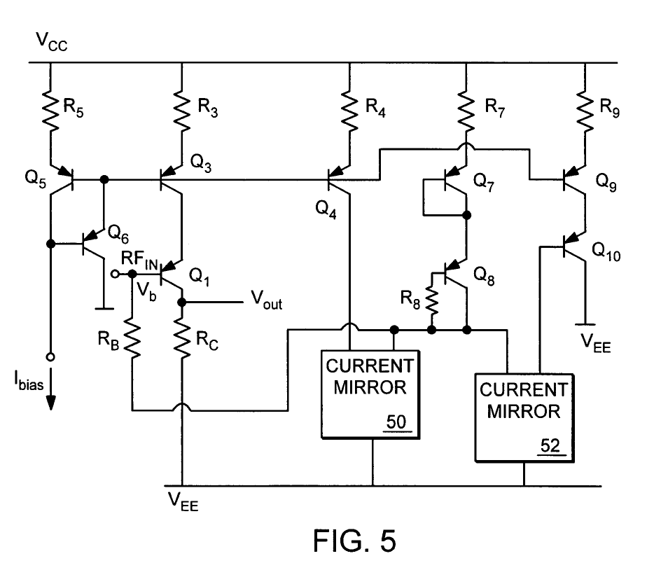

In the embodiments shown in FIGS. 3 and 4 all of the bipolar transistors are NPN. FIG. 5 is a circuit diagram of a single-ended amplifier and the biasing circuit shown in FIG. 4 with PNP bipolar transistors. The biasing circuit sets the quiescent base voltage for the bipolar transistor in the single-ended amplifier and compensates for process variations, changes in power supply voltage and changes in β due to temperature variation or process variation.

The single-ended amplifier includes primary bipolar transistor Q1, load resistor Rc and base resistor Rb. Load resistor Rc is coupled between the collector of bipolar transistor Q1 and power supply voltage V_{EE} to form the load for the single-ended amplifier. Base resistor Rb is coupled between the base of bipolar transistor Q1 and the biasing circuit. The single-ended input signal RFᵢₙ is A.C. coupled to the base of primary bipolar transistor Q1 through a capacitor (not shown). The differential output voltage V_{OUT} is the voltage at the collector of primary bipolar transistor Q1.

The biasing circuit sets the quiescent base voltage Vb for primary bipolar transistor Q1 in the single-ended amplifier and compensates for process variations, changes in power supply voltage and changes in β due to temperature variation or process variation.

The current source includes bipolar transistor Q6 and bipolar transistor-resistor pairs Q3-R3, Q4-R4, Q5-R5 and Q9-R9 and provides a constant emitter current to bipolar transistor Q1. The base bias circuit includes a primary biasing circuit which includes primary biasing bipolar transistor Q8 and a secondary biasing circuit including secondary biasing bipolar transistor Q10. The primary biasing circuit including primary biasing bipolar transistor Q8, bias resistor R8, bipolar transistor Q7 and resistor R7 sets the quiescent base voltage Vb for primary bipolar transistor Q1. The secondary biasing circuit includes bipolar transistor Q9, resistor R9 and secondary biasing bipolar transistor Q10 and tracks changes in the base current to primary bipolar transistors Q1 to compensate for changes in β in primary bipolar transistor Q1.

The primary biasing bipolar transistor Q8 receives current from a first current mirror 50. Primary biasing bipolar transistor Q8 tracks resistance variations with temperature in the base resistors RB to compensate for changes in voltage across base resistors RB. By connecting R8 between the base and collector of primary biasing bipolar transistor Q8, the matching of bias resistor R8 with base resistor RB is not dependent on primary biasing bipolar transistor Q8's β value. Instead, the match is only dependent on geometric matching of base resistor Rb and bias resistor R8.

The secondary biasing circuit compensates for changes in β in bipolar transistor Q1 by tracking changes in base current to primary bipolar transistor Q1. Secondary biasing bipolar transistor Q10 has a β that tracks the β of the primary bipolar transistor Q1. The base current of bipolar transistor Q1 is mirrored by a second current mirror 52 and sourced through the base resistor RB. Thus, if there is a drop in β in bipolar transistor Q1 and, consequently, the demand for base current increases, this condition is reproduced by bipolar transistor Q10 and the necessary extra current for bipolar transistor Q is supplied by the second current mirror 50.

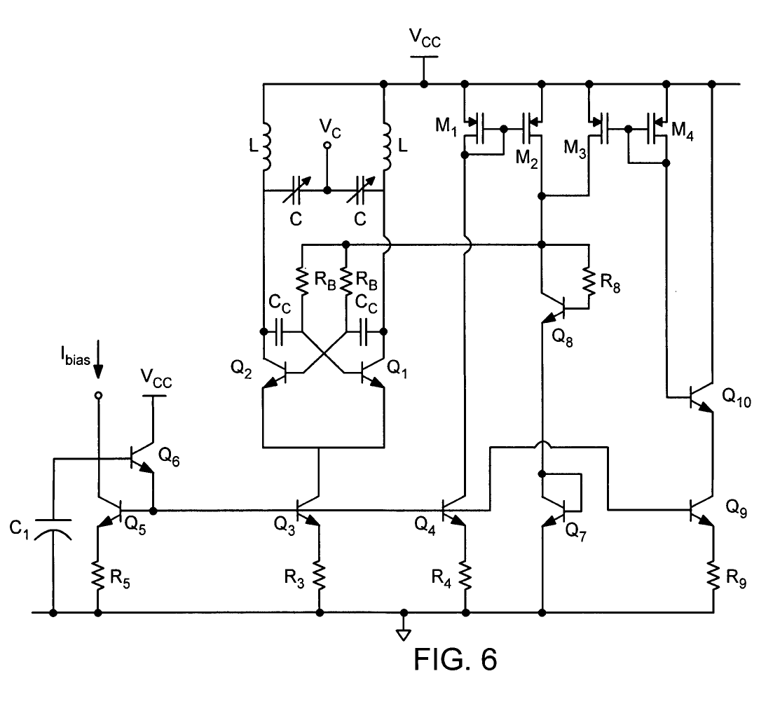

FIG. 6 is a schematic of a differential voltage controlled oscillator including the biasing circuit shown in FIG. 3. The behavior of this biasing circuit is the similar to the bias circuit described in conjunction with FIG. 3. Bipolar transistor Q7 matches bipolar transistor Q3, bipolar transistor Q8 matches bipolar transistor Q3 and bias resistor R8 matches base resistors RB. The collector voltage of bipolar transistor Q8 defines the quiescent collector voltage of primary bipolar transistors Q1-Q2 and the base voltage of primary biasing bipolar transistor Q8 defines the quiescent base voltage of primary bipolar transistors Q1, Q2. The base current of primary bipolar transistors Q1, Q2 is derived using secondary biasing bipolar transistor Q10 which is mirrored by a second current mirror including PMOS devices M3, M4 into the base resistors RB. The tracking of the base current for the primary bipolar transistors Q1, Q2 ensures base current tracking over β variations.

The embodiment of the biasing circuit shown in FIG. 6 does not include an emitter resistor for Q7 and exemplifies the situation described earlier in which R7 can be omitted. One desirable feature of the biasing circuit described in conjunction with FIGS. 3 through FIG. 6 is that the base-current tracking network constituted by secondary biasing circuit including bipolar transistors Q10, Q9 and resistor R9 does not require additional voltage headroom. This is in contrast to alternative approaches in which, for example, the current supplied to the primary biasing circuit including bipolar transistors Q8, R8 and resistor Q7, could be maintained over changes in β by providing the collector voltage of bipolar transistor Q8 to the base resistors RB by means of a voltage buffer. The latter approach may require undesirable voltage level shifts, dissipate more power, and it may prove less effective for very high frequency applications.

While this invention has been particularly shown and described with references to preferred embodiments thereof, it will be understood by those skilled in the art that various changes in form and details may be made therein without departing from the scope of the invention encompassed by the appended claims.

What is claimed is:

1. A bipolar transistor circuit comprising:
a primary bipolar transistor;
a base resistor through which a bias voltage is applied to the base of the primary bipolar transistor;
a current source that drives emitter current through the primary bipolar transistor; and
a base bias circuit generating the bias voltage and comprising:
a current mirror circuit which tracks current through the current source;
a primary biasing bipolar transistor having a β which tracks the β of the primary bipolar transistor and which receives current through the current mirror circuit to develop the bias voltage; and
a secondary biasing circuit comprising a secondary biasing bipolar transistor having a β which tracks the β of the primary bipolar transistor, the secondary biasing bipolar transistor receiving current from the current mirror circuit, changes in base current to the secondary biasing bipolar transistor causing changes in current to the primary biasing bipolar transistor.

2. The circuit of claim 1 further comprising a bias resistor coupled between the bias voltage and the base of the primary biasing bipolar transistor, the bias resistor tracking resistance variations in the base resistor.

3. The circuit of claim 1 wherein the primary bipolar transistor, the primary biasing bipolar transistor and the secondary biasing bipolar transistor are NPN.

4. The circuit of claim 1 wherein the primary bipolar transistor, the primary biasing bipolar transistor and the secondary biasing bipolar transistor are PNP.

5. The circuit of claim 1 wherein the primary bipolar transistor is one of a pair of bipolar transistors in a differential amplifier.

6. The circuit of claim 1 wherein the primary bipolar transistor is one of a plurality of bipolar transistors in a differential voltage controlled oscillator.

7. The circuit of claim 1 wherein the current mirror circuit includes a first current mirror which provides collector current to the primary biasing bipolar transistor and a second current mirror which tracks base current through the secondary biasing bipolar transistor.

8. A method for biasing a bipolar transistor comprising the steps of:
driving emitter current from a current source through a primary bipolar transistor;
generating a bias voltage by tracking current through the current source in a current mirror circuit the current received through the current mirror circuit by a primary biasing bipolar transistor having a β which tracks the β of the primary bipolar transistor;
tracking changes in current to the primary biasing bipolar transistor by a secondary biasing circuit comprising a secondary biasing bipolar transistor having a β which tracks the β of the primary bipolar transistor, the secondary biasing bipolar transistor receiving current from the current mirror circuit, changes in base current to the secondary biasing bipolar transistor causing changes in current to the primary biasing transistor; and
applying the bias voltage through a base resistor to the base of a primary bipolar transistor.

9. The method of claim 1 further comprising:
tracking resistance variations in the base resistor through a bias resistor coupled between the bias voltage and the base of the primary biasing bipolar transistor.

10. The method of claim 1 wherein the primary bipolar transistor, the primary biasing bipolar transistor and the secondary biasing bipolar transistor are NPN type.

11. The method of claim 1 wherein the primary bipolar transistor, the primary biasing bipolar transistor and the secondary biasing bipolar transistor are PNP.

12. The method of claim 1 wherein the primary bipolar transistor is one of a pair of bipolar transistors in a differential amplifier.

13. The method of claim 1 wherein the primary bipolar transistor is one of a plurality of bipolar transistors in an oscillator.

14. The method of claim 1 wherein the current mirror circuit includes a first current mirror which provides collector current to the primary biasing bipolar transistor and a second current mirror which tracks base current through the secondary biasing bipolar transistor.

15. An apparatus for biasing a bipolar transistor comprising:
means for driving emitter current from a current source through a primary bipolar transistor;
means for generating a bias voltage by tracking current through the current source in a current mirror circuit the current received through the current mirror circuit by a primary biasing bipolar transistor having a β which tracks the β of the primary bipolar transistor;
means for tracking changes in current to the primary biasing bipolar transistor by a secondary biasing circuit comprising a secondary biasing bipolar transistor having a β which tracks the β of the primary bipolar transistor, the secondary biasing bipolar transistor receives current from the current mirror circuit, changes in base current to the secondary biasing bipolar transistor causing changes in current to the primary biasing transistor; and
means for applying the bias voltage through a base resistor to the base of a primary bipolar transistor.

16. A bipolar transistor circuit comprising:
a primary bipolar transistor;
a base resistor through which a bias voltage is applied to the base of the primary bipolar transistor;
a current source that drives emitter current through the primary bipolar transistor; and
a base bias circuit generating the bias voltage and comprising:
a current mirror circuit which tracks current through the current source;
a primary biasing bipolar transistor having a β which tracks the β of the primary bipolar transistor and which receives current through the current mirror circuit to develop the bias voltage; and
a bias resistor coupled between the bias voltage and the base of the primary biasing bipolar transistor, the bias resistor tracking resistance variations in the base resistor.

17. The circuit of claim 1 wherein the primary bipolar transistor and the primary biasing bipolar transistor are NPN.

18. The circuit of claim 1 wherein the primary bipolar transistor and the primary biasing bipolar transistor are PNP.

19. The circuit of claim 1 wherein the primary bipolar transistor is one of a pair of bipolar transistors in a differential amplifier.

20. The circuit of claim 1 wherein the primary bipolar transistor is one of a plurality of bipolar transistors in an oscillator.
